(19) United States
(12) Patent Application Publication
(10) Pub. No.: US 2006/0014326 A1
(43) Pub. Date: Jan. 19, 2006

(54) Method for fabricating a semiconductor component with contacts situated at the underside

(75) Inventors: Albert Auburger, Regenstauf (DE); Hainz Oswald, (US); Helga Hainz, Burglengenfeld (DE); Dietmar Lang, Regenstauf (DE); Rudolf Lehner, Laaber (DE); Stefan Paulus, Zeitlarn (DE); Martin Petz, Eglhausen (DE); Michael Weber, Mainburg (DE)

Correspondence Address: LERNER AND GREENBERG, PA, P O BOX 2480, HOLLYWOOD, FL, 33022-2480, US

(73) Assignee: Infineon Technologies AG

(21) Appl. No.: 11/220,341

(22) Filed: Sep. 6, 2005

Related U.S. Application Data
(62) Division of application No. 10/210,977, filed on Aug. 2, 2002.
Application No. 10/210,977 is a continuation of application No. PCT/DE01/00386, filed on Jan. 31, 2001.

(30) Foreign Application Priority Data
Feb. 2, 2000 (DE) 100 04 410.7

(51) Int. Cl. H01L 21/44

(52) U.S. Cl. 438/123

(57) ABSTRACT

A semiconductor component has a housing with a first main area and a second main area opposite to the first main area, which surrounds at least one semiconductor chip. The semiconductor chip has a first metallization layer on a first main side. A second main side of the semiconductor chip borders the second main area of the semiconductor component. The first metallization layer of the semiconductor chip is connected via electrical conductors to contacts that are likewise surrounded by the housing and border the second main area. The semiconductor chip furthermore has, on the second main side, a second metallization layer for carrying signals.

### CROSS-REFERENCE TO RELATED APPLICATION

This is a divisional application of application Ser. No. 10/210,977, filed Aug. 2, 2002; which was a continuing application, under 35 U.S.C. §120, of International application PCT/DE01/00386, filed Jan. 31, 2001; the application also claims the priority, under 35 U.S.C. §119, of German patent application No. 100 04 410.7, filed Feb. 2, 2000; the prior applications are herewith incorporated by reference in their entirety.

### BACKGROUND OF THE INVENTION

Field of the Invention

The invention relates to a method for fabricating a semiconductor component having a housing with a first main area and a second main area opposite to the first main area, which surrounds at least one semiconductor chip. The semiconductor chip has a first metallization layer on a first main side. A second main side of the semiconductor chip extends to the second main area of the semiconductor component. The first metallization layer of the semiconductor chip is connected via electrical conductors to contacts that are likewise surrounded by the housing and extend to the second main area of the semiconductor component.

The present invention can be employed for example in logic or high-frequency semiconductor components. It can readily be employed in other types of semiconductor components, too, such as in memory components, for example. In particular, however, it is suitable for low-frequency or high-frequency applications in which the semiconductor component has a small number of contacts. These might be, for example, semiconductor switches, diodes or the like.

In such semiconductor components, the semiconductor chips are usually mounted on metal lead frames, on laminate substrates or ceramic substrates functioning as a chip carrier. The semiconductor chip is then contact-connected either using a wire bonding technique or a flip-chip technique. The semiconductor chip is encapsulated generally by encapsulation by transfer molding. The contact connections or contact pads of the component are situated at the underside of the semiconductor component. Since the semiconductor components have no customary pin connections, one talks of so-called “leadless semiconductor components” and of “leadless chip carriers” (LCC).

With “leadless chip semiconductor components”, it is possible to realize a significantly higher number of connections in comparison with conventional components given the same area on a printed circuit board. As an alternative, given an identical number of connections, a significantly smaller area could be obtained compared with a conventional semiconductor component, a smaller structural height of the components being obtained at the same time. In high-frequency applications especially, this affords advantages by virtue of the short signal paths and the compact configuration of the semiconductor components. The good linking of the semiconductor component to the printed circuit board and the small device dimensions have a favorable effect on the mechanical loadability and the affixing on the printed circuit board.

In leadless housings with a maximum of ten contacts, for example diodes or semiconductor switches with device dimensions of less than 2 mm, a ceramic substrate is predominantly used as a carrier for the semiconductor chip. The ceramic substrate is plated-through. The electrical connection of the contact pads, which are situated on a side of the semiconductor chip that is remote from the ceramic substrate, takes place by bonding wires. The semiconductor chip and the bonding wires are subsequently provided with a housing material. The use of a ceramic substrate in the case of individual semiconductors is associated with high costs. This is unavoidable, however, since the use of a metal lead frame is not possible on account of the size of the semiconductor chips and the dimensions of the finished semiconductor component.

Published, European Patent Application EP 0 773 584 A2 discloses various semiconductor components which dispense both with the use of a metal lead frame and with a ceramic substrate. The semiconductor components described therein have a housing made of a plastic potting compound which surrounds the semiconductor chip and has contacts on a main area of the semiconductor component. In this case, the contacts are either applied on projections that are part of the plastic housing, or else are provided in the form of simple metallization layers in the housing, the latter then terminating flush with the main area of the semiconductor component. The semiconductor components shown therein in part require a very complicated process sequence during fabrication. However, the fabrication of individual semiconductors requires the simplest possible method steps, cost-effective materials and housing configurations.

### SUMMARY OF THE INVENTION

It is accordingly an object of the invention to provide a method for fabricating a semiconductor component with contacts situated at the underside, that overcomes the above-mentioned disadvantages of the prior art devices and methods of this general type, which can be fabricated in the simplest possible manner and is suitable in particular for the use of individual semiconductors.

With the foregoing and other objects in view there is provided, in accordance with the invention, a semiconductor component. The semiconductor component contains a housing having a first main area and a second main area opposite the first main area and at least one semiconductor chip surrounded by the housing and having a first main side and a second main side adjacent the second main area of the housing. A first metallization layer is disposed on the first main side of the semiconductor chip. Contacts are provided that are surrounded by the housing and adjacent the second main area of the housing. Electrical conductors connect the first metallization layer to the contacts. A second metallization layer for carrying signals is disposed on the second main side of the semiconductor chip.

The invention provides a semiconductor component for low/high-frequency applications that can be fabricated extremely cost-effectively and is suitable in particular for so-called “low-pin” applications.

The advantages of the semiconductor component according to the invention can be understood with reference to the fabrication method explained in more detail below. In a first step, a base substrate is provided, which, as a conventional lead frame, may contain for example copper, an alloy or an organic material. The base substrate may be embodied as a continuous strip or in strips. The base substrate does not require previous processing; in other words, neither stampings nor a prior deformation are necessary. The base substrate is consequently completely flat. Only in a refinement is provision made for providing the base substrate with elevations. The elevations can be fabricated e.g. by an embossing operation or by etching. It may be advantageous to apply alignment marks on the base substrate, which can be used for alignment during subsequent processes. The alignment marks may be applied, for example, by a laser application, etching, embossing, stamping or printing.

In the next step, a semiconductor chip is provided which has a first metallization layer on a first main side and a second metallization layer on a second main side. In this case, the first metallization layer may be configured in the form of contact pads on the semiconductor chip. In an advantageous refinement, the second metallization layer may completely cover the at least one semiconductor chip on the second main side. If the semiconductor chip is, for example, a diode or a semiconductor switch, then the second main side of the semiconductor chip constitutes an active area. The second metallization layer is also referred to as rear-side metallization.

In a further step, the at least one semiconductor chip is applied to the base substrate, the second metallization layer and the base substrate facing one another. The application of the semiconductor chip to the base substrate may be realized by die bonding. The die bonding is then advantageously carried out by an alloying step. For this purpose, it is advantageous if the second metallization layer is gold-coated. Instead of an alloy, conductive adhesives or a soldering process could likewise be used in order to connect the at least one semiconductor chip to the base substrate. If the base substrate has been provided with elevations, the at least one semiconductor chip is applied to an elevation. In this case, the area of the semiconductor chip can be adapted to the area of the elevation. This is not absolutely necessary, however. The semiconductor chip could also project over the elevation; the elevation could likewise have a larger area than the semiconductor chip.

The next method step contains the application of at least one contact on the base substrate. In this case, the contacts are positioned on the base substrate in such a way that they are assigned to a semiconductor chip, on the one hand, and, on the other hand, are positioned at the locations which constitute the later connection areas of the semiconductor component. In an advantageous manner, the contacts assigned to a semiconductor chip are disposed adjacent to at least one side edge of the at least one semiconductor chip.

In an embodiment of the semiconductor component as an individual semiconductor, the semiconductor component has up to ten contacts. The contacts, in an embodiment as balls, may contain gold. In this case, application using a customary wire bonder is possible. As an alternative, the contacts may also be embodied as semiconductor laminae. In this case, the fixing technique of the at least one semiconductor chip and of the semiconductor laminae on the base substrate is possible in an identical manner. The semiconductor chip and the semiconductor laminae can also be provided with an identical metallization layer in a later processing step. The metallization layer (solder layer) serves to ensure simple and good connectability to a printed circuit board, for example. Moreover, the semiconductor laminae have the advantage over gold balls that their form can be configured as desired. They are advantageously made square, since a contact connection between the contact and the first metallization layer on the at least one semiconductor chip can then be produced in a particularly simple manner, for example by a bonding wire. In contrast to gold balls, the contact of a semiconductor lamina with a bonding wire cannot become brittle.

After the application of the at least one contact on the base substrate, in the next fabrication step, an electrical connection is produced between the at least one contact and the first metallization layer. The connection can be effected by a customary bonding wire. If the semiconductor component according to the invention is intended to contain a plurality of semiconductor chips in a housing, then it is conceivable for the first metallization layers of the at least two semiconductor chips to be electrically connected to one another. In this case, a multichip module can be produced in a simple manner.

In the case of a base substrate provided with elevations, it is not necessary to apply contacts in the form of gold balls or semiconductor laminae, since the elevations themselves form the contacts. The “contact elevations” are already present at the desired location in the base substrate. Consequently, a bonding wire can be directly applied to the “contact elevation”.

The next method step contains the application of a housing, which advantageously contains a plastic potting compound and is applied e.g. by transfer molding. The housing is configured in such a way that it surrounds the at least one semiconductor chip and the contacts assigned (that is to say electrically connected) thereto. Since a multiplicity of semiconductor chips accommodated in a multiplicity of different semiconductor components are applied on a base substrate, the form of the mold body can surround an individual semiconductor chip, semiconductor chips disposed in strips in a single housing or semiconductor chips disposed in a grid in a housing. Any customary thermosetting plastic or thermoplastic can be used as the plastic potting compound.

In the next method step, for fabricating the semiconductor component, the base substrate is completely removed. The removal of the base substrate can be carried out wet-chemically, by plasma etching, by grinding or by material-removing processing. The removal of the base substrate is carried out until the second main area of the semiconductor component with the second metallization layer, now extending to the second main area, and the at least one contact appears. In the case of a substrate provided with elevations, the removal of the base substrate is ended upon reaching the housing, so that the elevations remain in the housing. A solder layer can subsequently be applied to the second metallization layer and the contacts, which terminate flush with the second main area of the housing. The solder layer may be configured for example as a gold diffusion stop layer or a layer suitable for soldering.

In a concluding step, the semiconductor components are singulated, for example by a laser, by milling, by sawing or by a water jet. It goes without saying that the semiconductor chips surrounded with a potting compound were applied on a fixing before the removal of the base substrate. The fixing may be effected from commercially available UV film or on vacuum chucks or by the mold body itself.

Other features which are considered as characteristic for the invention are set forth in the appended claims.

Although the invention is illustrated and described herein as embodied in a semiconductor component with contacts situated at the underside, and a fabrication method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1a-1d are diagrammatic, cross-sectional views of a semiconductor component according to the invention, which is still applied on a base substrate;

FIGS. 2a-2c are plan views of the semiconductor components according to the invention from FIGS. 1a-1c;

FIGS. 3a-3c are cross-sectional views of semiconductor components according to the invention in which a solder layer is applied to a second metallization layer and contacts;

FIG. 4 is a cross-sectional view of the semiconductor component according to the invention that has two semiconductor chips;

FIG. 5 is a plan view of a further embodiment of the semiconductor component according to the invention;

FIG. 6 is a cross-sectional view of a base substrate on which there is applied plastic housings that have been produced by potting encapsulation in different ways; and

FIG. 7 is a plan view of the base substrate from FIG. 6.

### DESCRIPTION OF THE PREFERRED EMBODIMENTS

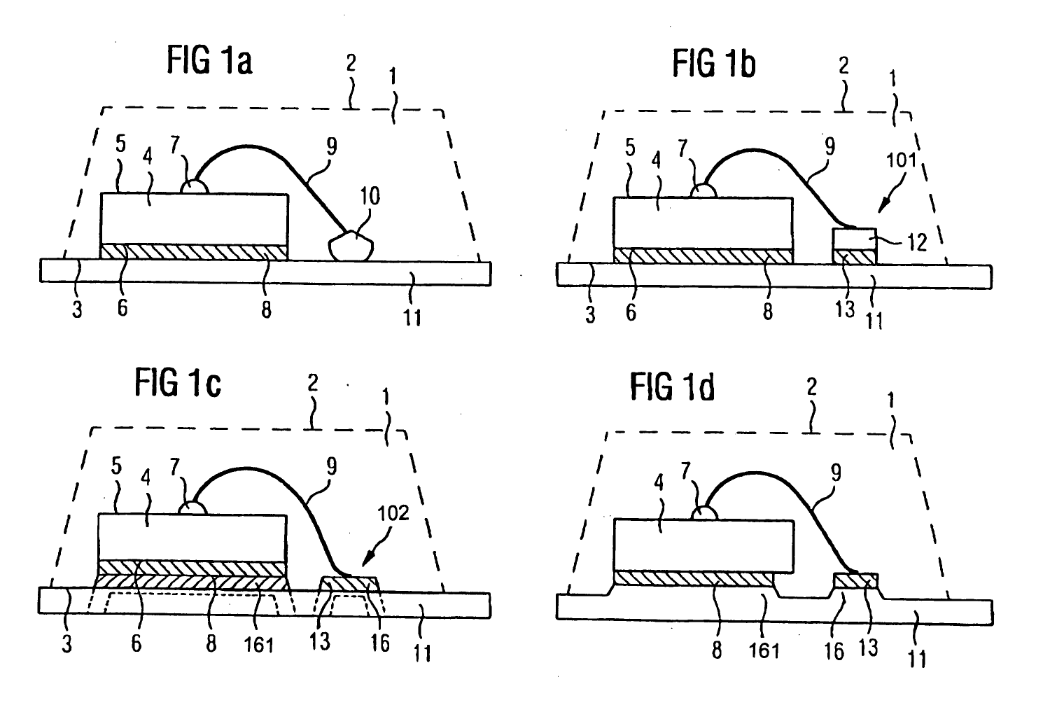

Referring now to the figures of the drawing in detail and first, particularly, to FIG. 1a thereof, there is shown a semiconductor component according to the invention on a base substrate 11 (with or without a refinement layer (Ag, Pd, etc.)) before the base substrate 11 has been removed. A semiconductor chip 4 with a first metallization layer 7 and a second metallization layer 8 is applied on the base substrate 11. In this case, the second metallization layer 8 is in direct contact with the base substrate 11. A contact 10, embodied as a gold ball, is applied on the base substrate 11 adjacent to the right-hand side edge of the semiconductor chip 4. The electrical connection between the contact 10 and the first metallization layer 7, which constitutes contact pads of the semiconductor chip 4, is performed by a bonding wire 9. The semiconductor chip 4 and the contact 10 are surrounded by a housing 1, which has been applied to the base substrate 11 by transfer molding, for example.

FIG. 1b shows a configuration that is basically identical to FIG. 1a. It differs merely by the fact that, instead of a gold ball 10, a semiconductor lamina 101 is provided which is connected to the base substrate 11 via a metallization layer 13. In this case, the metallization layer 13 and the second metallization layer 8 of the semiconductor chip preferably contain the same material, as a result of which the semiconductor chip 4 and at least the metallization layer 13 of the semiconductor lamina 101 can be applied in a single method step.

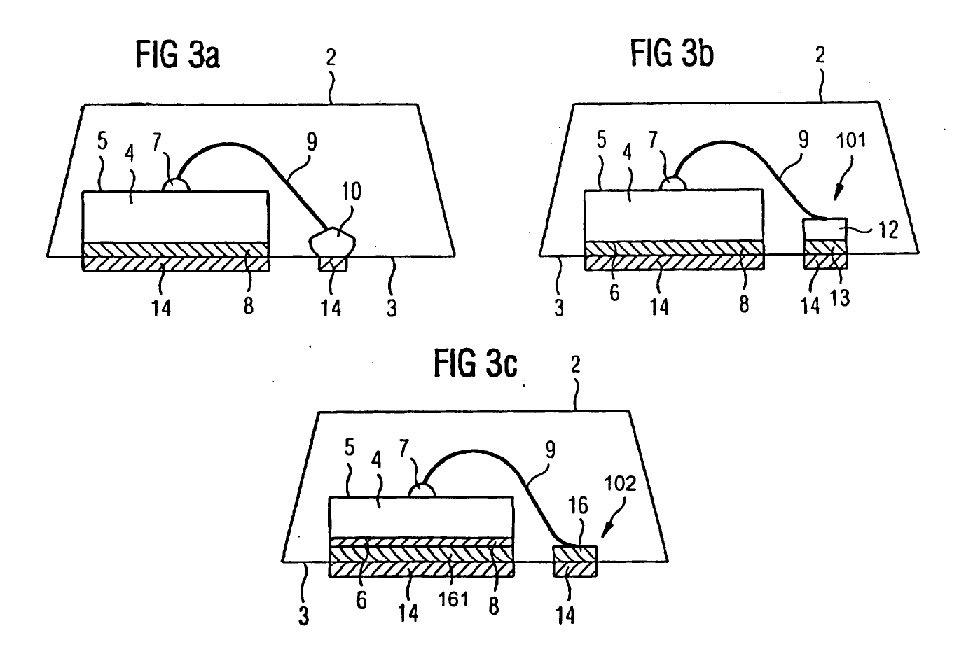

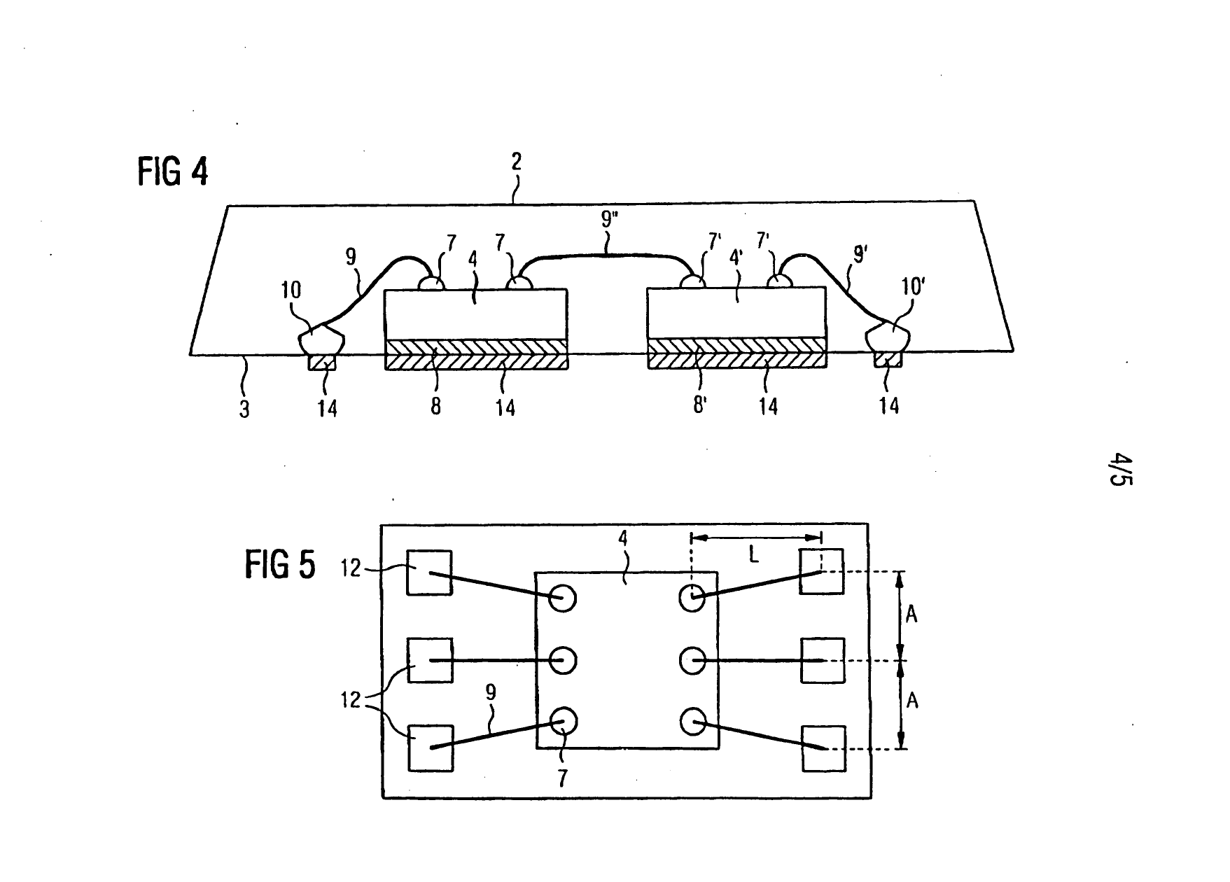

What is essential to the semiconductor components shown in FIGS. 1a and 1b is the fact that both the second metallization layer 8 and the contacts 10, 101 are in direct contact with the base substrate 11. After removal of the base substrate 11, for example by an etching process, the second metallization layer 8 and the contacts 10, 101 lie flush in one plane with a second main area 3 of the semiconductor component 1. This can be seen from FIGS. 3a, 3b, in which the second metallization layer 8 and the contacts 10, 101 are already provided with a solder layer 14 in order to enable the electrical connection of the semiconductor component to a printed circuit board, for example, in a known manner. The application of the solder layer 14 is not absolutely necessary, however. A soldering contact could also be produced by hot-dip tinning.

In FIG. 1c, the semiconductor chip 4 is applied to an elevation 161 that, in the present exemplary embodiment, is adapted to the size of the semiconductor chip 4 and is produced by embossing. The bonding wire 9 is applied directly to an elevation 16, serving as a contact 102. In this case, the elevation 16, 161 is permitted to extend at most as far as the second main area 3 of the semiconductor component, in order that an externally contact-connectable contact is also produced after the removal of the base substrate 11. In the present FIG. 1c, the elevation 16, 161 does not extend as far as the second main area 3 of the semiconductor component. Therefore, a part of the elevation 16, 161 (that is to say the part which extends as far as the second main area 3) is concomitantly removed during the removal of the base substrate, thereby producing a planar area (see FIG. 3c).

It can be seen from FIG. 1d that the elevations 16, 161 can also be fabricated by etching, from the second main area 3. In contrast, the other main area of the substrate is planar. As is illustrated in FIG. 1d, the semiconductor chip 4 can also project laterally beyond the elevation 161. This may also be the case on both sides.

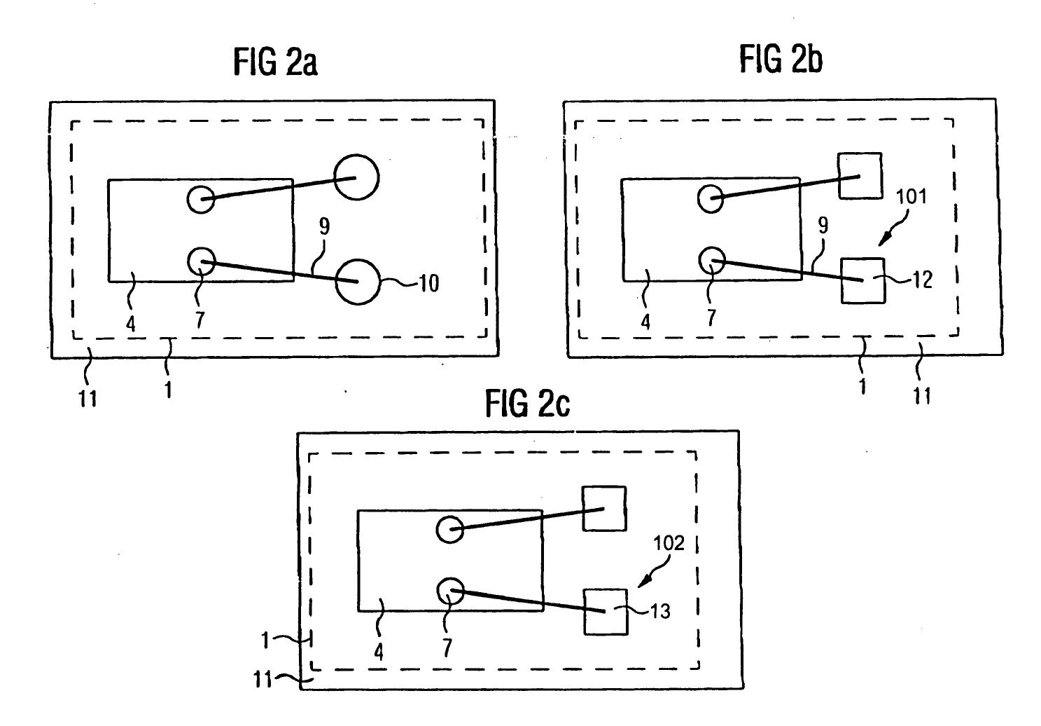

FIGS. 2a-2c show plan views of the semiconductor components according to the invention in accordance with FIGS. 1a-1c. In the present exemplary embodiments, the semiconductor chips 4 each have two contact pads formed by the first metallization layer 7. The latter are connected to a respective contact 10, 101, 102 via the bonding wires 9. As revealed by FIG. 2a, the contacts 10, which are embodied as gold balls there, has a round form. In contrast thereto, the contacts 101 in FIG. 2b are made square. The semiconductor laminae 12 can be configured, in principle, in any conceivable form. The same applies to the elevations 16, 161, which can be configured as desired. They have a square form in FIG. 2c. A square configuration enables, in particular, simple connection of the bonding wire 9 to the surface of the semiconductor lamina 12.

The number of contact pads of the first metallization layer 7 could, of course, also deviate from the exemplary embodiments shown in FIGS. 1a to 3c. The semiconductor element according to the invention is suitable in particular, but not exclusively, for low-pin configurations. Low-pin configurations contain up to ten contacts 10, 101, 102, disposed adjacent to the semiconductor chip 4. The contacts 10, 101, 102 can then be disposed for example along the outer edges of the semiconductor chips 4.

FIG. 4 shows a second exemplary embodiment of a semiconductor component according to the invention. The semiconductor component has two semiconductor chips 4, 4′, which are disposed next to one another. Each of the two semiconductor chips 4, 4′ has a first metallization layer 7, 7′ and a second metallization layer 8, 8′. In this case, the second metallization layers 8, 8′ extend flush in one plane to the second main area 3 of the semiconductor component 1. The contact pads of the first metallization layer 7, 7′ are respectively connected to a contact 10, 10′ via bonding wires 9. The contacts 10, 10′ likewise extend to the second main area 3 of the semiconductor component 1. The second metallization layers 8, 8′ and also the contacts 10, 10′ are each covered with a solder layer 14. In the present exemplary embodiment, in each case one contact pad 7, 7′ of the semiconductor chips 4, 4′ is connected to one another via a bonding wire 9″. The semiconductor chips 4, 4′ are thus able to exchange signals with one another. However, it would also be conceivable for there not to be an electrical connection between the semiconductor chips 4, 4′ and for the latter merely to be accommodated in a housing. Furthermore, in an alternative configuration, it is possible to provide a plurality of semiconductor chips in the semiconductor component 1.

FIG. 5 is a plan view of a further exemplary embodiment of a semiconductor component according to the invention. In this exemplary embodiment, the semiconductor chip 4 has six contact pads 7, which form the first metallization layer on the first main side of the semiconductor chip 4. Each of the contact pads 7 is connected via the bonding wire 9 to the contact 10, which is embodied here as the semiconductor lamina 12. In principle, it is possible to vary a distance A between the contacts 10 as desired. It is likewise possible to vary as desired a distance L between a contact pad 7 and the respectively assigned contact 10. By of its fabrication method, the semiconductor component according to the invention enables an extremely flexible configuration of the contacts with regard to the semiconductor chip. Consequently, it is possible to set, in principle, any desired “pitch spacing”.

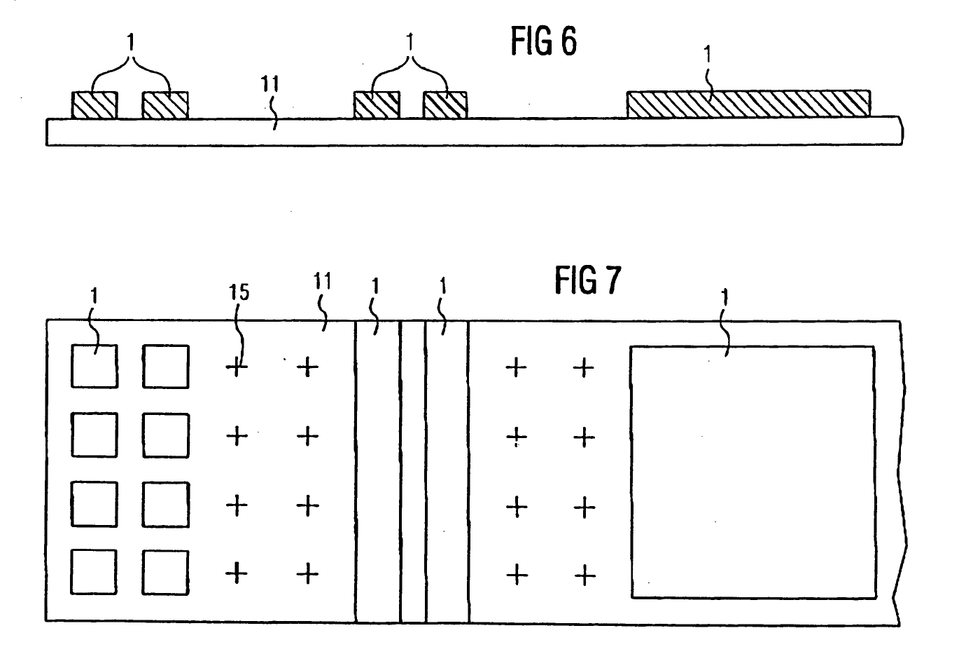

FIGS. 6 and 7 each show the base substrate 11 in the case of which housings 1 have been applied in different configurations. In this case, a multiplicity of semiconductor chips and contacts assigned thereto are applied in a regular configuration, e.g. in a grid, on the base substrate 11. The left-hand half of FIG. 6 reveals that, when the semiconductor chips and the non-illustrated assigned contacts are encapsulated by potting, each configuration can be individually encapsulated by molding. On the other hand, it is also conceivable, as is illustrated in the center of FIG. 6, to accommodate semiconductor chips disposed in a row in a single housing 1. Likewise, the semiconductor chips disposed in a grid can be surrounded by a single housing 1. In the two last-mentioned cases, therefore, it is not necessary to fix the semiconductor components by a film before they are singulated. The fixing is effected by the mold body itself. By laser cutting, it is likewise possible to achieve any desired outer form of the package, which ensures better space utilization on the circuit board.

The invention thus enables cost-effective fabrication of a semiconductor component that can be employed in particular in individual semiconductors. It is possible to use the materials known from the prior art for the semiconductor component itself and for the base substrate. In particular, the procedure according to the invention has the advantage that a treatment of the base substrate, for example metallization, stamping or embossing, is not necessary but, as described, is possible. The layout, that is to say the configuration of the contacts with regard to a semiconductor chip, can be affected highly flexibly. Therefore, the base substrate need never be varied. Furthermore, it is possible to realize a very high device density on the base substrate since only the width for a sawing cut, laser cut, water jet or milling track has to be provided between the individual semiconductor components.

The invention furthermore enables both multichip and single-chip semiconductor components. Only during the application of the housing is it ascertained whether the intention is to fabricate a single-chip or a multichip module. Again it is not necessary to modify the base substrate. The use of a semiconductor chip metallized on both sides makes it possible to use vertically integrated individual semiconductors. In this way, it is possible to obtain very small dimensions of the semiconductor chip and, consequently, of the entire semiconductor component. In the case of a chip size of 0.3×0.3×0.14 mm, the dimensioning of the housing is then e.g. 0.8×0.5×0.4 mm.

We claim:

1. A method for fabricating a semiconductor component, which comprises the steps of:
providing a base substrate;
providing at least one semiconductor chip having a first metallization layer and a second metallization layer;
applying the semiconductor chip to the base substrate such that the second metallization layer and the base substrate face one another;
applying contacts on the base substrate;
producing an electrical connection between the contacts and the first metallization layer;
applying a housing so that the semiconductor chip and the contacts are surrounded; and
removing the base substrate.

2. The method according to claim 1, which comprises forming the base substrate as a metallic conductor having an elevation at locations of at least one of the semiconductor chip and the contacts.

3. The method according to claim 2, which comprises removing the base substrate by etching.

4. The method according to claim 3, which comprises ending the etching step as soon as the housing is reached, so that the elevation at the locations of the semiconductor chip and the contacts are surrounded by the housing.

5. The method according to claim 1, which comprises refining the second metallization layer of the semiconductor chip and the contacts using a method selected from the group consisting of chemical deposition, electro-deposition, and hot-dip tinning.

6. The method according to claim 1, which comprises providing a plurality of semiconductor chips disposed in a grid form on the base substrate.

7. The method according to claim 6, which comprises forming the housing to surround the plurality of semiconductor chips disposed in the grid form.

8. The method according to claim 1, which comprises forming the base substrate from a material selected from the group consisting of copper, an alloy, and an organic material.

9. The method according to claim 1, which comprises providing the base substrate with alignment marks which have been applied before an application of the semiconductor chip using a method selected from the group consisting of lasing, etching, embossing, stamping and printing.

10. The method according to claim 1, which comprises providing a plurality of semiconductor chips disposed next to one another in a row and the housing surrounds the plurality of semiconductor chips.

11. A method for fabricating semiconductor components, which comprises the steps of:
providing a base substrate;
providing a plurality of semiconductor chips each having a first metallization layer and a second metallization layer;
applying the semiconductor chips to the base substrate such that the second metallization layer and the base substrate face one another;
applying contacts on the base substrate;
producing an electrical connection between the contacts and the first metallization layer;
applying a housing so that the semiconductor chips and the contacts are surrounded;
removing the base substrate; and
singulating the semiconductor chips for forming the semiconductor components.
